(19) United States
(12) Patent Application Publication
(10) Pub. No.: US 2003/0159907 A1
(43) Pub. Date: Aug. 28, 2003

(54) Method and device for transporting electronic components

(76) Inventor: Johannes Gerhardus Augustinus Zweers, Wehl (NL)

Correspondence Address: John W McIlvaine, 700 Koppers Building, 436 Seventh Avenue, Pittsburgh, PA, 15219-1818, US

(21) Appl. No.: 10/257,555

(22) PCT Filed: Apr. 9, 2001
(86) PCT No.: PCT/NL01/00283

(30) Foreign Application Priority Data
Apr. 14, 2000 (NL) 1014955
Apr. 27, 2000 (NL) 1015030

(51) Int. Cl. H05K 13/02

(52) U.S. Cl. 198/728; 198/347.4; 198/734; 198/735.3; 198/493

(57) ABSTRACT

The invention relates to a method for transporting separated electronic components by advancing along a guide electronic components located in said guide using a pusher member mounted on an endless transporter. The invention also provides a device for transporting electronic components, comprising: a guide, at least one endless transporter disposed on the sides of the guide, and at least one pusher member coupled to the endless transporter for engaging electronic components for displacing along the guide.

The invention relates to a method for transporting electronic components according the preamble of claim 1. The invention also relates to a device for transporting electronic components according the preamble of claim 5.

In the known method for transporting electronic components the separated components are displaced under the influence of the force of gravity over an inclining guide. A drawback of this transporting method has been revealed particularly due to the present trend towards size-reduction of the electronic components. In extreme cases these size-reduced electronic components have a very limited mass (for instance in the order of magnitude of hundredths of a gram). The transport of these small electronic components does not function properly due to very minor disturbances such as for instance contaminants. When transport is monitored by sensors the transporting device will then come to a halt until the problem is remedied.

U.S. Pat. No. 5,190,431 discloses a transfer apparatus for IC's and the like. An essential element in the transfer apparatus as disclosed in this document is a moveable air blower. The electronic devices are displaced in an electronic device magazine with a stopper at one end and an opening at the other end. By air pressure all the electronic components in a magazine are moved one by one to until an opening is created betveen the stopper and the electronic component closest to the stopper. In the created opening a piston pin is placed between the stopper and the electronic component closest to the stopper. The piston pin preferably moves in a step by step manner so to expel the electronic devices from the device magazine. The piston pin is carried by an advancing apparatus connected to a continuous belt. The invention according this document is specifically related to transportation of electronic devices from a single guide that is blocked on one side.

The present invention has for its object to provide an improved method and device for transporting electronic components, with which small electronic components in particular can also be displaced in high capacity on a simple manner.

The present invention provides to this end a method for transporting electronic components according claim 1. Using this method the electronic components are displaced by means of extremely simple forced movements at an optionally constant transporting speed. In contrast with the transport know from the closest prior art the transportation according the invention does not require positioning of the pusher member relative to the components to be transported. The relatively low mass of small components is hereby no longer a source of disturbances. Light components will after all also undergo the forced displacements without complex equipment being necessary for the purpose. Another important advantage of the method according the present invention is that an accurate positioning of the pushing member in the direction rectangular to the direction of transportation is irrelevant; the pusher member is advanced by two endless conveyor belts located on either side avoiding the risk of tilting the components to be transported (and thus the risk of jamming of the components). Another advantage of the present invention is that it enables a continuous movement of the puncher member. Another advantage is that the pusher member does not have to be form-retaining and can therefore shape itself to the electronic components for pushing.

The international patent application WO 00/03566 of the present applicant describes a device and method with which electronic components are displaced in a special buffer by an intermittent transporting member. In practise it is found difficult to displace very small electronic components in particular in this manner, partly due to the fact that the precision with which the intermittent transporting member has to operate must be very great.

The pusher member is preferably advanced between a lower guide and an upper guide for electronic components. The electronic components can thus be enclosed from a direction other than the transporting direction so that undesired release of the components from the guide is impossible. The ensured positioning of the components in the guide is particularly advantageous for small components since due to disturbances caused by for instance contaminants or air flow there is a greater danger of them being dislodged from a guide which only engages on one side.

A gas is preferably blown through the guide in the transporting direction. A considerable part of the electronic components will thus already be carried along by the gas, generally blow air, and only a limited number of the components (those components encountering more resistance during displacement) still comes into contact with the pusher member. Carrying the electronic components along with a gas moreover has the advantage that the components will exert no or only limited forces on adjacent components displaced along a guide. This gas blowing through the guide can not be compared with the compressed air according the closed prior art; according the invention a precise positioning of the gas is irrelevant; it is not required to separate components.

In a very advantageous application of the method a gas is exhausted close to the guide. Through exhausting of a gas, generally ambient air, contaminants will also be discharged. Particles of encapsulating material (epoxy) represent a particularly great problem in practice in the processing of moulded chips, since it has a considerable hardness. Exhausting is not normally possible in the prior art transport because it impedes displacement of the electronic components. However, the forced displacement of the components by means of the pusher member makes it less problematic that exhausting a considerable air volume will influence the forced displacement of the components.

The present invention also provides a device for transporting electronic components, according claim 5. In a preferred embodiment of the device the guide is a guide with a plurality of adjacent tracks. Such a device is simple to construct and can moreover be given a very robust form. Nor due to the relatively simple construction is maintenance of the device very complex. If the width of the pusher member is sufficiently great, components can be pushed simultaneously in a plurality of tracks with a single pusher member, even when the tracks do not run mutually parallel, such as when the mutual distance between the tracks of the guide varies along the length of the guide. These advantages can not be realised with the transfer apparatus according the closest prior art. The pusher member does not have to be form-retaining but can take on a shape subject to the contact with one or more components. The pusher member can thus be wire-like and assembled with the two endless transporters.

In yet another preferred embodiment of the device the guide comprises an upper guide and a lower guide for guiding the electronic components on at least two sides. Owing to this dual guiding the components can be secured on opposite sides such that they cannot leave the guide in undesired manner. As a consequence hereof it is for instance also possible to allow the components to come into contact with air flows without there being any danger of the loss of components. The upper guide and the lower guide will of course have to be embodied such that the pusher member can be moved there between; a slot opened for instance to one side must be present for this purpose between the upper guide and lower guide.

The device can also be equipped with blowing means for generating a gas flow along the guide, which gas flow can carry along at least some of the components even before they are advanced by the pusher member. The advantages hereof have already been described with reference to the method according to the invention. The advantages of the preferred embodiment of the device, wherein exhausting means connect onto the guide for exhausting ambient gas such as air, have also already been stated above.

The present invention will be further elucidated with reference to the non-limitative embodiment shown herein below. Herein:

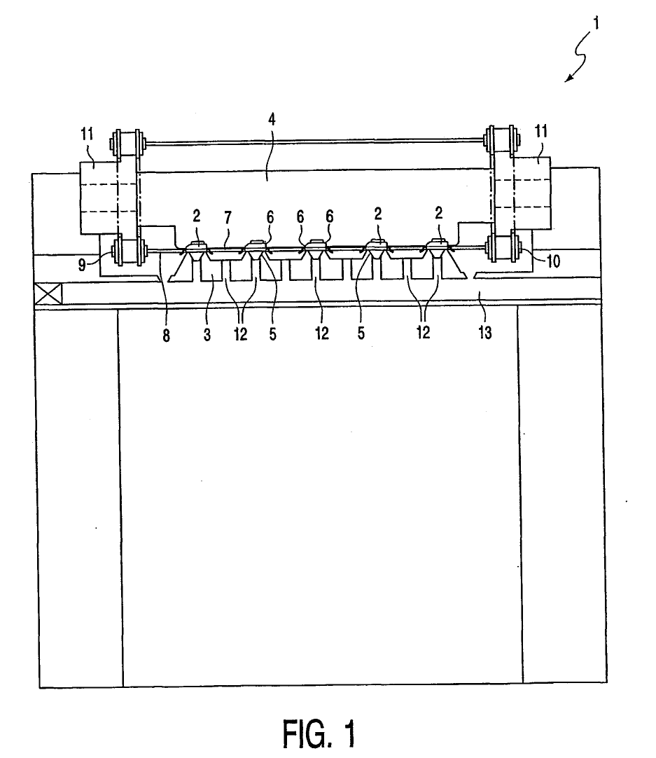

FIG. 1 shows a schematic cross-section through a device according to the invention,

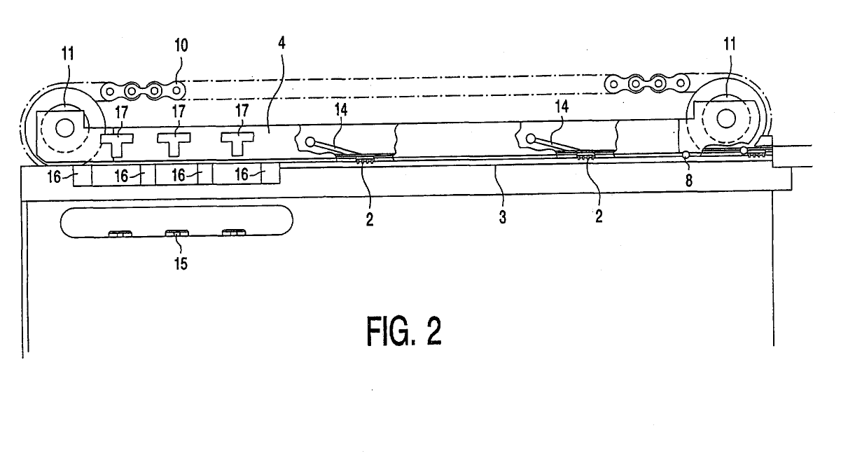

FIG. 2 shows a partly cut-away side view of the device as depicted in FIG. 1, and

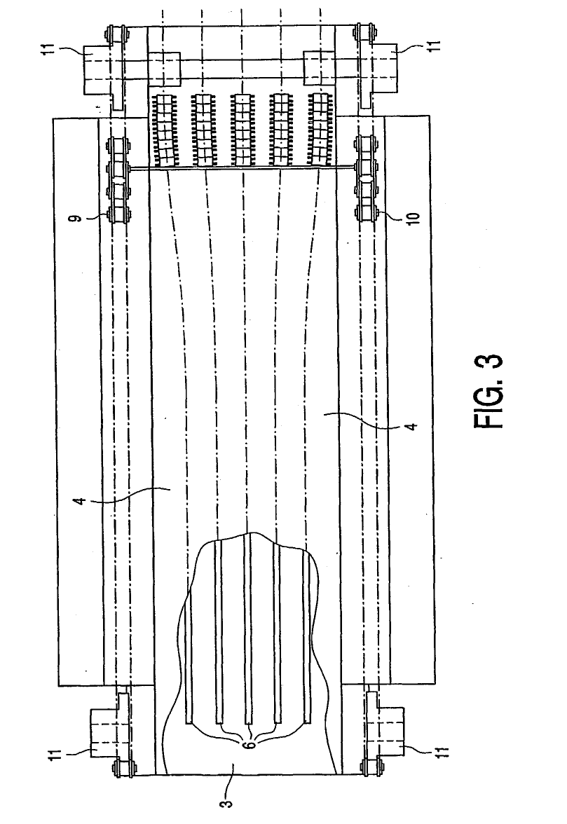

FIG. 3 shows a partly cut-away top view of the device as depicted in FIGS. 1 and 2.

FIG. 1 shows a device 1 for transporting electronic components 2. Device 1 is provided for this purpose with a lower guide 3 and an upper guide 4, both provided with tracks 5 respectively 6 connecting onto each other, between which electronic components 2 are displaceable. Between lower guide 3 and upper guide 4 is a slot-like opening 7 through which a wire-like pusher member 8 can be displaced. Wire-like pusher member 8 is connected to two endless transport chains 9,10 which are displaceable by transporter wheels 11.

FIG. 1 also shows that lower guide 3 is provided with exhaust ducts 12 which are opened towards the contact side of guide 3 and which connect onto a central exhaust conduit 13 which leads to a pump, (not shown). By means of exhaust ducts 12 air can be exhausted from slot-like opening 7, wherein contaminated particles are simultaneously also discharged. In addition to the very simple method of transporting electronic components 2, another advantage of device 1 is that fewer contaminants are left behind on electronic components 2, which is also very desirable for further processing thereof.

FIG. 2 shows device 1 in side view wherein the transport chain 10 and transporter wheels 11 are clearly shown. Shown in cut-away parts of upper guide 4 are air ducts 14 with which an air flow can be generated, whereby in normal conditions the electronic components 2 are displaced between guides 3,4. Only in the case an electronic component 2 encounters an increased resistance (for instance due to contaminants, misalignment and so on) will this component be pushed by a wire-like pusher member 8.

FIG. 2 also shows that a separation unit 15 is incorporated in lower guide 3 so that device 1 is not only adapted to transport electronic components 2 but also to release them from a collective carrier. The combination of transporter and separation unit 15 also forms part of the invention. For separation of components 2 a cutting plate 16 is arranged in upper guide 4. The thus separated components 2 are brought to the correct height by positioning pins 17, with which a back pressure can be applied during separation.

FIG. 3 finally shows device 1 in partly cut-away top view. The partly removed part of the upper guide 4 reveals a part of lower guide 3 with parallel running tracks 6 for guiding electronic components 2. A second part of lower guide 3 can be seen at the end of the transport path of device 1. The tracks 6 filled with components 2 here no longer run parallel but diverge. The distance between adjacent rows of electronic components can thus be changed in device 1, for instance in order to adjust this distance to storage holders or storage tubes (not shown).

Although the invention is elucidated with reference to only a single embodiment, it will be apparent to all that the invention is in no way limited to the described and shown embodiment. On the contrary, many more variations are possible for the skilled person within the scope of the invention.

1. Method for transporting electronic components (2) by advancing along a guide (3,4) electronic components (2) located in said guide (3,4) using a pusher member (8) mounted on an endless transporter (9,10),
characterised in that the pusher member (8) is advanced with two endless transporters (9,10) located on either side of the guide (3,4).

2. Method as claimed in claim 1, wherein the pusher member (8) is advanced between a lower guide (3) and an upper guide (4) for electronic components (2).

3. Method as claimed in claim 1 or 2 any of the foregoing claims, wherein a gas is blown through the guide (3,4) in the transporting direction.

4. Method as claimed in any of the foregoing claims, wherein a gas is exhausted close to the guide (3,4).

5. Device (1) for transporting electronic components (2), comprising:
a guide (3,4),
an endless transporter (9,10) disposed on the sides of the guide (3,4), and
at least one pusher member (8) coupled to the endless transporter (9,10) for engaging electronic components (2) for displacing along the guide (3,4),
characterised in that the device (1) comprises two endless transporters (9,10) which are disposed adjacently of opposing sides of the guide (3,4) for at least a part of the transport path, and the pusher member (8) is assembled with the two endless transporters (9,10).

6. Device (1) as claimed in claim 5, wherein the guide (3,4) is a guide (3,4) with a plurality of adjacent tracks (5,6).

7. Device (1) as claimed in claim 8, wherein the mutual distance between the tracks (5,6) of the guide (3,4) varies along the length of the guide (3,4).

8. Device (1) as claimed in any of the claims 5-7, wherein the guide (3,4) comprises an upper guide (3) and a lower guide (4) for guiding the electronic components (2) on at least two sides.

9. Device (1) as claimed in any of the claims 5-8, wherein the pusher member (8) is wire-like.

10. Device (1) as claimed in any of the foregoing claims, wherein the device (1) also comprises blowing means for generating a gas flow along the guide (3,4).

11. Device (1) as claimed in any of the foregoing claims, wherein exhausting means (12,14) connect onto the guide (3,4) for exhausting ambient gas.
